(19) United States
(12) Patent Application Publication
(10) Pub. No.: US 2025/0377417 A1
(43) Pub. Date: Dec. 11, 2025

(54) ANOMALY DETECTION IN AN ENVIRONMENT OR SYSTEM

(71) Applicant: COMMISSARIAT A L'ENERGIE ATOMIQUE ET AUX ENERGIES ALTERNATIVES, Paris (FR)

(72) Inventor: Andrea VASSILEV, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/231,836

(22) Filed: Jun. 9, 2025

(30) Foreign Application Priority Data
Jun. 10, 2024 (FR) FR2406090

(51) Int. Cl. G01R 33/00; G01V 3/08; G01V 13/00

(52) U.S. Cl. CPC G01R 33/0029; G01V 3/087; G01V 13/00

(57) ABSTRACT

A device and a method for detecting anomalies, including: acquiring a normal signal reflecting a normal state, determining on the basis of the normal signal a probability density ƒ which models a normal behavioral state, setting an information filter based on the probability density ƒ, the information filter being configured to converge toward a limit value L when it is applied to samples of a normal signal, while increasing its value in response to the detection of an anomaly, setting a threshold value S based on the convergence limit value, acquiring a current signal reflecting the current behavioral state, sampling the current signal in a current series of N samples, computing a result of applying the information filter to the current series of N samples, comparing the result with the threshold value S, an anomaly being detected if the result exceeds the threshold value.

### TECHNICAL FIELD

The present invention relates to the field of anomaly detection and, more particularly, it is aimed at identifying behaviors deviating from a standard or ambient behavior.

### PRIOR ART

Anomaly detection encompasses a variety of varied techniques and finds applications in many industrial sectors.

For example, the detection of a ferromagnetic target, which induces a magnetic anomaly in the environment, illustrates one of the many possible applications of these techniques. Many applications make use of the magnetic field for detecting, locating and tracking objects, offering accurate solutions in visually demanding contexts.

Such a method is described by Sheinker et al. in the article “Magnetic Anomaly Detection Using an Entropy Filter”, published in Measurement Science and Technology, vol. 19, no. 045205. Available online: https://doi.org/10.1088/0957-0233/19/4/045205.

This method suggests modeling the normal behavior of the environment using a continuous probability density function, denoted as ƒ. A sliding window, Wᵢ which contains N samples (where N is generally equal to 30), is defined as follows:

$${W}_{i} = \{ {x}_{i - N + 1} , {x}_{i - N + 2} , … , {x}_{i - 1} , {x}_{i} \} \qquad [ Math . 1 ]$$

A discretization step, denoted as Δ, is also set. Next, a filter is applied to the window Wᵢ and it is computed as follows:

$$M 1 ( {x}_{i} ) = - {\sum }_{{x}_{k} ∈ {W}_{i}} Δ f ( {x}_{k} ) log ( Δ f ( {x}_{k} ) ) \qquad [ Math . 2 ]$$

The presence of a magnetic anomaly is detected when the value of the filter falls below a determined threshold S:

$$M 1 ( {x}_{i} ) < S \qquad [ Math . 3 ]$$

The main challenge of this method is the difficulty setting a suitable threshold for two main reasons. Firstly, the optimal value of the threshold is not known initially. Secondly, the threshold is influenced both by the length of the sliding window, N, and the degree of discretization, Δ.

In particular, it is critical to highlight that the appropriate choice of Δ is decisive for the efficiency of the detector. For example, consider an oversized value of Δ: this could cause the filter to react counterintuitively, increasing rather than decreasing in the presence of an anomaly, and in this case, the anomaly is never detected.

Another method has been described by Zhou et al. in the article entitled “Magnetic anomaly detection via a combination approach of minimum entropy and gradient orthogonal functions”, published in ISA Transactions, volume 134, pages 548-560. Available online: https://doi.org/10.1016/j.isatra.2022.08.026.

Zhou's method uses the same approach as Sheinker, and defines a filter as follows:

$$M 2 ( {x}_{i} ) = - {\sum }_{{x}_{k} ∈ {W}_{i}} f ( {x}_{k} ) log ( f ( {x}_{k} ) ) \qquad [ Math . 4 ]$$

The presence of a magnetic anomaly is detected when the value of the filter falls below a determined threshold S:

$$M 2 ( {x}_{i} ) < S \qquad [ Math . 5 ]$$

The method proposed by Zhou offers the advantage of avoiding the need for a discretization step Δ for signal processing. However, like with the previous approach, determining a suitable threshold proves to be complex, because its optimum value is not known initially and it is also affected by the dimension of the sliding window N. Adjusting the threshold according to the length of the sliding window proves to be particularly laborious, given that the size of the window can vary. Consequently, conventional methods often require a laborious trial-and-error process to determine the appropriate threshold.

The present invention aims to provide a device and a method for detecting anomalies overcoming the aforementioned drawbacks, by substantially simplifying the definition of the detection threshold.

### DISCLOSURE OF THE INVENTION

This aim is achieved with a method for detecting anomalies within an environment or system, comprising the following steps:
acquiring a normal signal reflecting the normal state of the environment or system,
determining on the basis of said normal signal, a probability density, denoted as ƒ, which models a normal behavioral state of the environment or system,
setting an information filter based on said probability density, said information filter being configured to converge toward a limit value when it is applied to samples of a normal signal, while increasing its value in response to the detection of an anomaly,
setting a threshold value based on said convergence limit value,
acquiring a current signal reflecting the current behavioral state of the environment or system,
sampling said current signal in a current series of N samples using a determined sliding window Wi,
computing a result of applying the information filter to said current series of N samples,
comparing said result with said threshold value, an anomaly being detected if said result exceeds said threshold value.

This method substantially enhances anomaly detection, ensuring high reliability, while being extremely simple to implement. Indeed, determining the threshold is intuitive and is performed easily, because it is based on the limit value which is intrinsically defined.

Advantageously, said threshold value is equal to said convergence limit value, plus an additional value chosen according to a compromise sought between reliable detection and minimizing the number of false alarms.

This facilitates simplified selection of the detection threshold according to the desired degree of accuracy and reliability for anomaly identification.

According to a first embodiment, the information filter corresponds to a first filter [symbol] designed such that, when it is applied to samples of a normal signal, it converges toward a limit value which corresponds to the entropy of the probability density associated with this normal signal.

This first filter ensures the automatic setting of the entropy of the probability density associated with the normal signal as the lower limit for the threshold.

Advantageously, applying said first filter Iᵢ to said current series of a determined number N of samples consists in computing the natural logarithm of the value of the probability density ƒ for each of the samples xₖ, then summing these logarithms, and multiplying the result of this sum by the negative factor corresponding to the inverse of said determined number N of samples, according to the following formula:

$${I}_{i} = - \frac{1}{N} {\sum }_{{x}_{k} ∈ {W}_{i}} log f ( {x}_{k} ) \qquad [ Math . 6 ]$$

Advantageously, said threshold value S is equal to the value of the entropy H(ƒ) of the probability density ƒ, plus a value ε within an interval ranging from 1% to 20% of the absolute value of said entropy, according to the following formula:

$$S = H ( f ) + ε \qquad [ Math . 7 ]$$

The added value chosen for the increase is determined carefully in order to achieve an optimal balance between the ability to reliably detect actual anomalies and minimizing the risk of generating incorrect alerts, i.e. false alarms.

According to a first example, said additional value is defined in a range between 10% and 20% of the absolute value of the entropy, in order to achieve a very low probability of false alarms, between 10⁻⁴ and 10⁻³.

According to a second example, said additional value is defined in a range between 1% and 10% of the absolute value of the entropy, to promote the probability of correct detection.

According to a second embodiment, the information filter corresponds to a second filter [symbol] which is based on said first filter described before, and uses a continuous function, denoted as g, which represents an approximation of the data probability density of the current signal S_{C} over a predetermined sliding window Wᵢ.

Applying said second filter [symbol] to said current series of a determined number N of samples consists in computing the natural logarithm of the value of the continuous function g for each of the samples, computing the average of the results obtained for these natural logarithms, and adding the result of said average to the result of the application of the first filter [symbol] to the same current series of samples, according to the following formula:

$${K}_{i} = \frac{1}{N} {\sum }_{{x}_{k} ∈ {W}_{i}} log g ( {x}_{k} ) + {I}_{i} \qquad [ Math . 8 ]$$

The invention also relates to a device for detecting anomalies within an environment or system, comprising:
an acquisition module configured to acquire a current signal reflecting the current behavioral state of the environment or system,
a processor configured for:
sampling said current signal in a current series of N samples using a determined sliding window Wi,
computing a result of applying an information filter to said current series of N samples, said information filter being based on a probability density modeling a normal behavioral state of the environment or system, said information filter being configured to converge toward a limit value when it is applied to samples of a normal signal, while increasing its value in response to the detection of an anomaly,
comparing said result with a threshold value based on said convergence limit value, an anomaly being detected if said result exceeds said threshold value, and
an output interface configured to indicate the detection of an anomaly.

According to a first application, the device comprises a magnetometer configured to generate said current signal by picking up an ambient magnetic field, comprising the Earth's field as well as various magnetic disturbances.

According to a second application, the device comprises an accelerometer (or a vibration sensor) configured to generate the current signal by picking up the vibrations originating from a machine to be monitored.

According to a third application, the device comprises a counter configured to generate the current signal by measuring the volume of data exchanged at a specific node of a computer network to be monitored.

According to a fourth application, the device comprises an eddy current probe configured to produce the current signal by measuring the thickness of a pipeline under monitoring.

### BRIEF DESCRIPTION OF THE DRAWINGS

The present invention will be better understood upon reading the following description of exemplary embodiments given for merely indicative and non-limiting purposes, with reference to the appended drawings, wherein:

FIG. 1 schematically illustrates a device for detecting anomalies within a technical environment or system, according to one embodiment of the invention;

FIG. 2 schematically illustrates a method for detecting anomalies within a technical environment or system, according to one embodiment of the invention;

FIG. 3 schematically illustrates a method for detecting anomalies within a technical environment or system, according to a first preferred embodiment of the invention;

FIG. 4A, FIG. 4B and FIG. 5A, FIG. 5B, FIG. 5C, FIG. 5D, FIG. 5E, FIG. 5F show the application of the present invention in anomaly detection by processing the data collected by a sensor, according to a specific implementation of the invention; and

FIG. 6 schematically illustrates a method for detecting anomalies within a technical environment or system, according to a first preferred embodiment of the invention.

### DETAILED DISCLOSURE OF PARTICULAR EMBODIMENTS

The underlying concept of the invention is that of providing a detection technique wherein the threshold is determined intuitively from a predefined value known in advance.

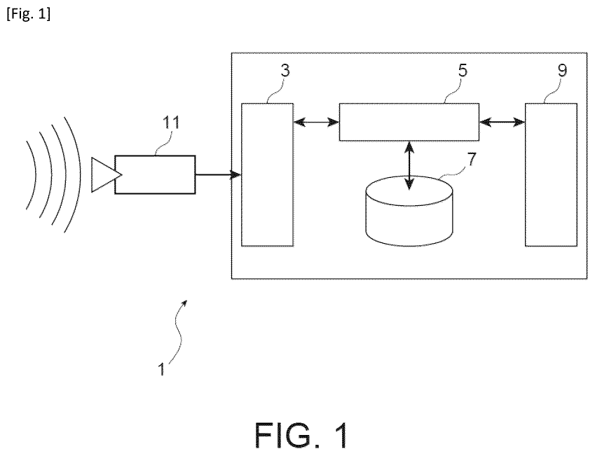

FIG. 1 schematically illustrates a device for detecting anomalies within a technical environment or system, according to one embodiment of the invention.

The device 1 for detecting anomalies comprises an acquisition module 3, a processor 5 which could be a microcontroller, a central processor or a microprocessor, a dedicated memory 7, as well as input/output interfaces 9.

The detection device 1 is adapted to acquire signals which may be different in nature according to the problem considered. For example, it may pick up magnetic signals via a magnetometer to identify ferromagnetic targets, vibration signals from a vibration sensor for tracking the state of a machine, or acoustic signals to check the integrity of a pipeline, among other applications. Consequently, the device 1 is designed to be equipped with or associated with a suitable sensor 11, according to the specificities of the intended application.

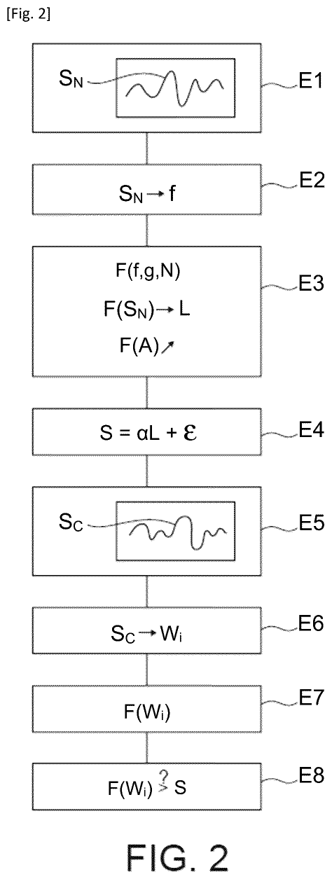

The detection device 1 is specifically designed to implement a detection method detailed in the diagram of FIG. 2.

Indeed, FIG. 2 schematically illustrates a method for detecting anomalies within a technical environment or system, according to one embodiment of the invention.

The method is structured around two phases: an initial calibration phase, described by steps E1 to E4, and an operational phase, dedicated to active anomaly detection, detailed in steps E5 to E8.

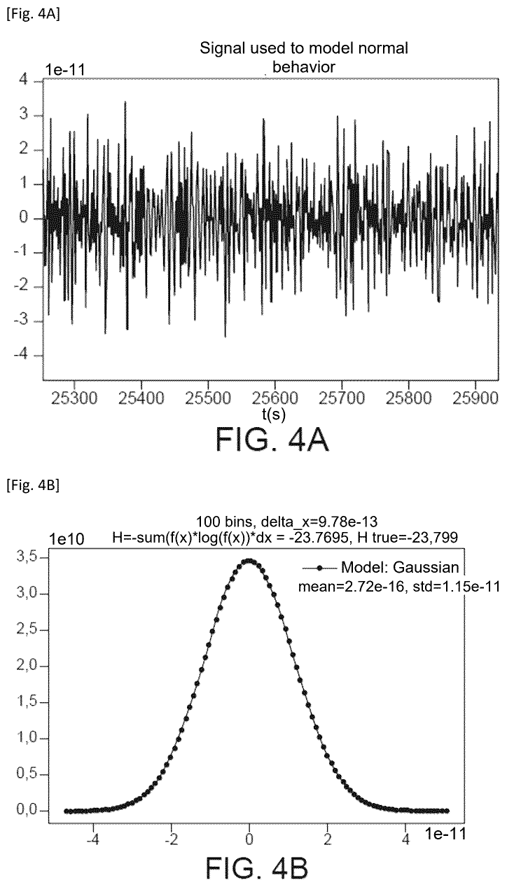

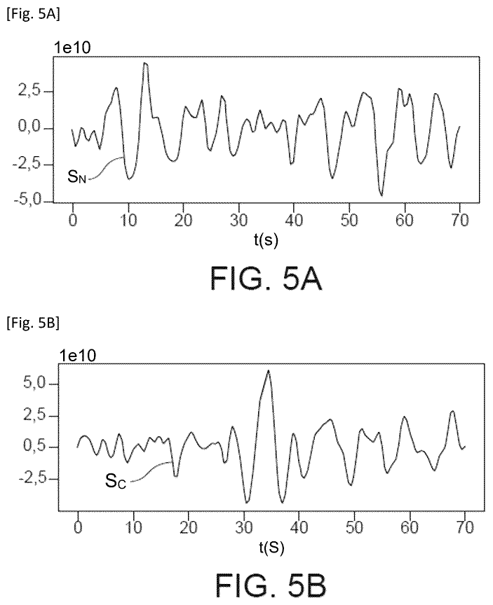

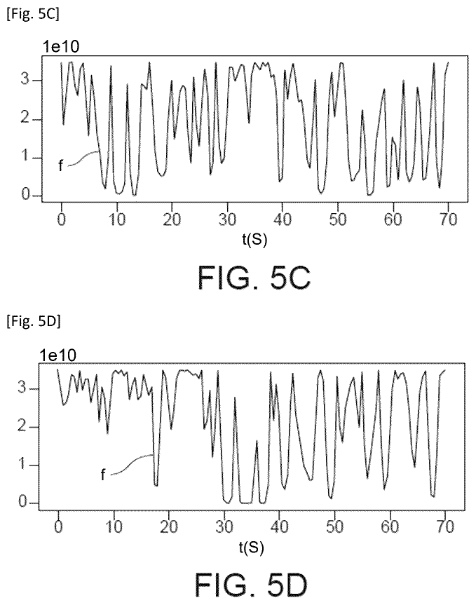

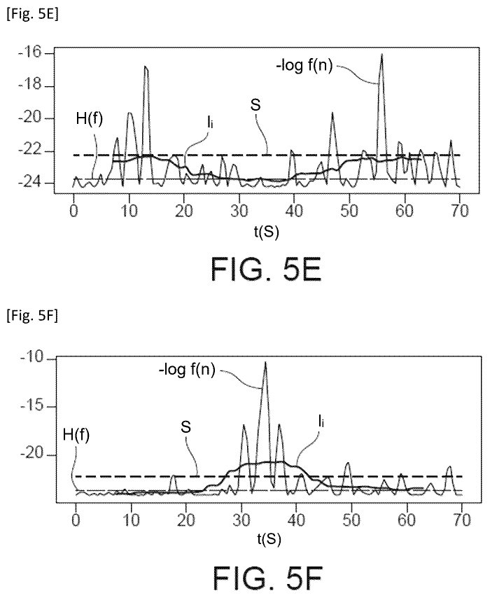

In step E1, the acquisition module 3 is configured to acquire a normal signal S_{N} reflecting the normal state of the environment or system. An example is represented by the time signal in the graph of FIG. 4A.

In step E2, the processor 5 is configured to determine a probability density, denoted as ƒ, which models a normal behavioral state of the environment or system studied. An example of probability density is given in the graph of FIG. 4B.

In step E3, the processor 5 is configured to set an information filter F based on the probability density ƒ. The information filter F is set taking into account the probability density ƒ and the size of the window N. It can also integrate a continuous function g constructed on the basis of a current signal. (For the inventor: here, the information filter ‘F’ is a filter which generalizes the two filters ‘Ii’ and ‘Ki’. Furthermore, without this generalization, we would be faced with an objection linked with the lack of unity of invention).

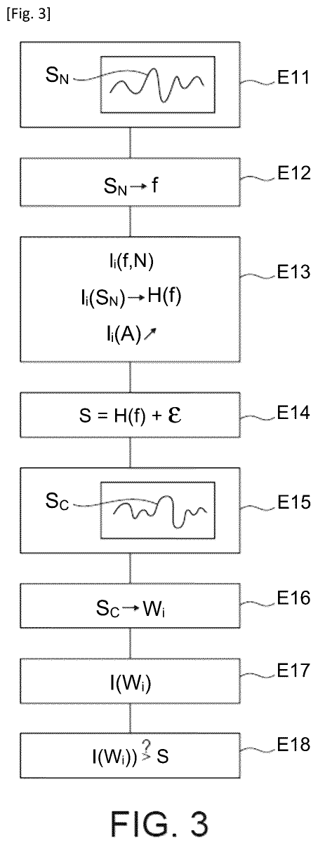

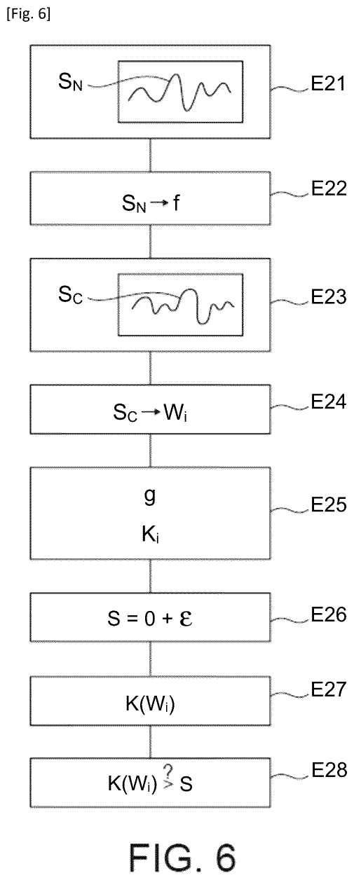

The information filter F(xₖ) converges toward a predefined limit value L when it is applied to samples of a normal signal S_{N}. Thus, it is simply necessary to use samples of a normal signal S_{N} to determine this limit value L. According to the example of a first embodiment, explained in relation to FIG. 3, the limit value L corresponds to the entropy of the probability density characterizing the normal state of the system or environment. According to the example of a second embodiment described in relation to FIG. 6, the limit value L corresponds to zero. Furthermore, the information filter F(xₖ) is characterized by an increase in its value in response to the detection of an anomaly ‘A’.

In step E4, the processor 5 is configured to set a threshold value S based on the convergence limit value L. Since the information filter F(xₖ) naturally tends toward a well-determined limit value L when it analyzes a normal signal S_{N}, and on the other hand it shows an increase in the event of an anomaly, the definition of the threshold value S becomes intuitive: it is set slightly above L so that, in operation, any value of the filter exceeding S signals an anomaly. For illustration, it is possible to model the threshold S as an affine function of L, according to the equation S=αL+ε, where α is a positive or zero adjustment factor and ε a small positive constant additional value, ensuring a margin above the limit value L for reliable detection of anomalies.

Advantageously, the threshold value S can simply be equal to the limit value L, plus the constant additional value ε. This additional value ε is chosen according to a compromise sought between reliable detection and minimizing the number of false alarms.

Within the detection device 1, the memory 7 stores the probability density function ƒ, the information filter F, the convergence limit value L as well as the value of the threshold S for efficient recall during the detection operations.

Steps E1 to E4 define the initial calibration phase which, once completed, does not need to be repeated for each new anomaly detection sequence.

Active anomaly detection starts at step E5, during which the processor 5 is configured to acquire a current signal S_{C} reflecting the current behavioral state of the environment or system to be monitored.

In step E6, the processor 5 is configured to sample the current signal S_{C} in an initial series of N samples using a determined sliding window Wi.

It should be pointed out that the size of the selected window is adjustable. This ability to adjust the size of the window is explained by the fact that, according to the present invention, the threshold value S is not linked to the adopted window size. The same threshold value S is applied, which ensures uniformity of the detection criterion.

In step E7, the processor 5 is configured to compute a result F( [symbol] ) of applying the information filter to the current series S_{C} of N samples.

In step E8, the processor 5 is configured to compare this result F( [symbol] ) with the threshold value S. An anomaly is detected if the result F( [symbol] ) exceeds the threshold value S. The detection of an anomaly can be signaled by the output interface 9 of the detection device 1.

FIG. 3 schematically illustrates a method for detecting anomalies within a technical environment or system, according to a first preferred embodiment of the invention.

In order to clarify the presentation of this method, it is explained with reference to the examples illustrated by FIGS. 4A to 5F.

FIGS. 4A to 5F show the application of the present invention in anomaly detection by processing the data collected by a sensor, according to a specific implementation.

According to this example, the detection device 1 is associated with a magnetometer 11 configured to generate the current signal by picking up an ambient magnetic field, comprising the Earth's field and various magnetic disturbances. For example, the magnetometer 11 is positioned on the Earth's surface in order to pick up variations in the local magnetic field. The recorded signal reflects the natural Earth's magnetic field, while including various interferences and parasitic noises, such as the magnetometer's 11 own noise and external geomagnetic disturbances.

FIG. 4A illustrates the standard profile of the magnetic field as measured in the absence of interference. On introducing a ferromagnetic object, such as a vehicle, into this environment, the magnetometer 11 will pick up variations superposed on the baseline signal. These variations or disturbances are described as anomalies. The main aim of the detection device 1 is that of detecting such anomalies with precision.

As previously established, the calibration phase, which extends from steps E11 to E14, is designated for defining the probability density function, the information filter, the convergence limit value and the threshold value.

In step E11, the acquisition module 3 is configured to acquire a normal signal S_{N} reflecting the normal state of the environment or system.

Such a signal S_{N} is illustrated in FIG. 4A. More specifically, this figure shows a graph of the magnetic signal recorded over a period of 1000 minutes which serves as the basis for establishing the standard behavioral model of the local magnetic field.

In step E12, the processor 5 is configured to determine the probability density ƒ which models the normal behavioral state of the environment or system studied.

By way of example, FIG. 4B shows a diagram which represents a Gaussian type probability density ƒ. The function ƒ is constructed by computing the mean and the variance on the basis of the normal signal shown in FIG. 4A. These computations are based on the following formulas:

$$μ = \frac{1}{N} {\sum }_{{x}_{k} ε {W}_{i}} {x}_{k} and {σ}^{2} = \frac{1}{N} {\sum }_{{x}_{} ε {W}_{i}} {( {x}_{k} - μ )}^{2} \qquad [ Math . 9 ]$$

Based on these parameters, the probability density ƒ can be expressed as follows:

$$f ( {x}_{k} ) = \frac{1}{\sqrt{2 {πσ}^{2}}} exp [ - \frac{{( {x}_{k} - μ )}^{2}}{2 {σ}^{2}} ] \qquad [ Math . 10 ]$$

Let us consider, for example, the normal signal of the Earth's magnetic field, observed over a period of 1000 minutes as illustrated in FIG. 4A. For this signal, it was determined that the mean is μ=2.72×10⁻¹⁶ and the standard deviation σ=1.15×10⁻¹¹.

It will be noted that the probability density function ƒ representing the normal behavior of a signal can be represented either by a continuous function, or by a histogram, according to the specific nature of the signal studied.

In step E13, the processor 5 is configured to set a mean information filter [symbol] , named ‘first filter’, which is based on the probability density function ƒ. This first filter is designed such that, when it is applied to a normal signal S_{N}, it converges toward a limit value which corresponds to the entropy of the probability density ƒ associated with this normal signal.

The first filter out of an initial series or a current series of a determined number N of samples consists in computing the natural logarithm of the value of the probability density ƒ for each of the samples xₖ in the set of N samples. The sum of these logarithms is then obtained, and the total is multiplied by the opposite of the inverse of the number N of samples, according to the following formula:

$${I}_{i} ( {x}_{k} ) = - \frac{1}{N} {\sum }_{{x}_{k} ∈ {W}_{i}} log f ( {x}_{k} ) \qquad [ Math . 11 ]$$

The value to which the output of the first filter tends, when the number of samples of the normal signal S_{N} increases indefinitely, corresponds to the entropy of the probability density, denoted as H(ƒ). This relationship is described by the following formula:

$${I}_{i} {\to }_{N \to ∞} H ( f ) = - {\int }_{x ∈ X} f ( x ) * log ( f ( x ) ) dx \qquad [ Math . 12 ]$$

where X corresponds to the set of possible values for x.

In step E14, the processor 5 is configured to set the threshold value S based on the value H(ƒ) of the entropy of the probability density ƒ associated with the normal signal S_{N}.

Advantageously, the threshold value S is equal to the value of the entropy H(ƒ) of the probability density ƒ, increased by a value ε within an interval ranging from 1% to 20% of the absolute value of the entropy H(ƒ), according to the following formula:

$$S = H ( f ) + ε \qquad [ Math . 13 ]$$

Thus, the choice of the threshold S is very simple; all it needs is to compute the entropy H(ƒ) of the probability density ƒ, and take this entropy plus a small value ε as the threshold value.

It should be pointed out that raising the additional value ε reduces the number of false alarms, but it can also reduce detection sensitivity and reliability. Conversely, by lowering the additional value ε, the reliability is enhanced thanks to better sensitivity, yet in exchange for an increase in false alarms. Consequently, the setting of this value ε can be carried out according to a balance between the correct detection rate and the risk of false alarms, according to the specific requirements of each application.

According to a first example, the additional value ε is defined in a range between 10% and 20% of the absolute value of the entropy, in order to achieve a very low probability of false alarms, between 10⁻⁴ and 10⁻³.

According to a further example, the additional value is defined in a range between 1% and 10% of the absolute value of the entropy, to promote achieving maximum reliability in anomaly detection.

For illustration purposes, let us take the entropy H(ƒ) computed for the probability density ƒ shown in FIG. 4B, which is set to H(ƒ)=−23.77. In order to promote sensitivity of the detection while accepting a higher rate of false alarms, it is possible to adopt a voluntarily low threshold value ε. By setting ε to 1.47, i.e. approximately 6% of the absolute value of H(ƒ), the detection threshold S is set to −22.3, which results in the sum of H(ƒ) and ε, i.e. S=−23.77+1.47=−22.3.

Steps E11 to E14 are designated for the initial calibration phase. Once this phase is completed, the operational detection of anomalies is launched, starting with step E15.

The remainder of the description is continued through FIGS. 5A to 5F, which are based on the same case study as that of FIGS. 4A and 4B. FIGS. 5A, 5C and 5E illustrate the results obtained for a signal considered as normal. In parallel, FIGS. 5B, 5D and 5F show the data corresponding to an ‘abnormal’ scenario, such as the presence of a vehicle near the sensor. More specifically, FIGS. 5A and 5B respectively show the recordings of a normal signal S_{N} and of a current signal S_{C} affected by an anomaly. FIGS. 5C and 5D show the probability density profiles associated with the data of FIGS. 5A and 5B, respectively. Finally, FIGS. 5E and 5F compare the filter results of the data of FIGS. 5A and 5B with the set threshold value, thus highlighting the presence or absence of anomalies. The values of the entropy H(ƒ)=−23.77 and the threshold value S=−22.3 are represented by the horizontal lines in FIGS. 5E and 5F.

In step E15, the processor 5 is configured to acquire a current signal S_{C} reflecting the current behavioral state of the environment or system to be monitored. This current signal S_{C} is shown in FIG. 5A in the scenario where it is a normal signal with no anomalies, or in FIG. 5B if it comprised anomalies.

In step E16, the processor 5 is configured to sample the current signal S_{C} in a series of N samples using a determined sliding window Wi.

$${W}_{i} = \{ {x}_{i - N + 1} , {x}_{i - N + 2} , ... , {x}_{i - 1 ,} {x}_{i} \} \qquad [ Math . 1 ]$$

In step E17, the processor 5 is configured to compute the result I(Wᵢ) of applying the first information filter to the current series of N samples. Indeed, the processor 5 first evaluates the probability density ƒ for the data xₖ from the current signal S_{C} illustrated in FIG. 5B. The curve ƒ(xₖ) which shows this probability density as a function of time is illustrated in FIG. 5D. The processor 5 is then configured to compute −log ƒ(xₖ), resulting in the corresponding curve shown in FIG. 5F. Finally, the processor 5 sums the logarithms of ƒ(xₖ) for N samples, where N=30 in this context. This sum is then multiplied by the opposite of the inverse of N, in accordance with the formula set out above. The result of the filter Iᵢ≡I(Wᵢ) is shown as a time curve in FIG. 5F.

In step E18, the processor 5 is configured to compare this result I(Wᵢ) with the threshold value S. An anomaly is detected if the result I(Wᵢ) exceeds the threshold value S:

$$I ( {W}_{i} ) > S \qquad [ Math . 14 ]$$

FIG. 5E illustrates that, for a normal signal S_{N}, the time curve corresponding to the filter I(Wᵢ) remains systematically below the threshold value set to S=−22.3. In contrast, FIG. 5F shows intervals where the time curve of the filter I(Wᵢ) associated with the current signal S_{C} rises above this threshold value. This overshoot signals the presence of an anomaly.

FIG. 6 schematically illustrates a method for detecting anomalies within a technical environment or system, according to a second preferred embodiment of the invention.

This method differs from that described in FIG. 3 essentially by the introduction of a filter, distinct from the first filter. According to this second embodiment, the information filter corresponds to a second filter which is based on the first filter described in FIG. 3.

In step E21, the acquisition module 3 is configured to acquire a normal signal S_{N} reflecting the normal state of the environment or system.

In step E22, the processor 5 is configured to determine on the basis of the normal signal S_{N} the probability density ƒ which models the normal behavioral state of the environment or of the studied system.

In step E23, the processor 5 is configured to acquire a current signal S_{C} reflecting the current behavioral state of the environment or system to be monitored.

In step E24, the processor 5 is configured to sample the current signal S_{C} in order to obtain a series of N samples, using a predefined sliding window Wi.

$${W}_{i} = \{ {x}_{i - N + 1} , {x}_{i - N + 2} , ... , {x}_{i - 1 ,} {x}_{i} \} \qquad [ Math . 1 ]$$

In step E25, the processor 5 is configured to approximate the probability density of the data of the current signal S_{C} on this sliding window Wᵢ by a continuous probability density g. The estimation of the probability density g can be performed using a histogram or by the non-parametric kernel estimation approach, also known as Kernel Density Estimation (KDE). KDE uses functions referred to as kernels to assign local weights, and makes it possible to obtain smoothing of data from a finite set of samples. This technique is particularly useful when the number of samples N is limited.

According to this second embodiment, applying the second filter, denoted as [symbol] , to an initial calibration series or a current series of a determined number N of samples by the processor 5 consists in first computing the natural logarithm of the value of the continuous function g for each of the samples. Then, the processor 5 proceeds to compute the arithmetic mean of the results obtained for these natural logarithms. This mean is subsequently added to the result of applying the first filter to the same series of samples. The formula used by the processor 5 is as follows:

$${K}_{i} = \frac{1}{N} {\sum }_{{x}_{k} ∈ {W}_{i}} log g ( {x}_{k} ) + {I}_{i} \qquad [ Math . 8 ]$$

When this second filter is applied to the samples of the normal signal S_{N}, its value converges toward zero. Furthermore, the value of the second filter increases in the presence of an anomaly, as for the first embodiment.

In step E26, the processor 5 is configured to set the threshold value S which is expressed simply according to the following formula:

$$S = 0 + ε \qquad [ Math . 15 ]$$

Therefore, determining the threshold S is even simpler than in the first embodiment. It is not necessary to compute the entropy H(ƒ) because it is simply necessary to take a small fixed value ε. The latter must always be adjusted according to a compromise between the probability of correct detection and the probability of a false alarm.

In step E27, the processor 5 is configured to compute the value [symbol] ≡K(Wᵢ) resulting from applying the second information filter to the current series of N samples.

Finally, in step E28, the processor 5 is configured to compare the value K(Wᵢ) obtained previously with the threshold S. The detection of an anomaly is confirmed if K(Wᵢ) exceeds the threshold value S:

$$K ( {W}_{i} ) > S \qquad [ Math . 16 ]$$

It should be noted that the present invention, illustrated by a detailed example associated with FIGS. 4A-4B and 5A-5F for an application scenario involving a magnetic signal and the detection of a ferromagnetic object, is adapted to be implemented in other applications.

A first application example is the detection of attacks in a computer network. For this situation, a relevant time series, denoted as Xt, T (where ‘t’ refers to time), registers the amount of data measured in bytes or bits transiting via a node of the network over the time interval [t; t+T]. The sensor used is then a counter configured to generate the current signal by measuring the volume of data exchanged at a specific node of the computer network to be monitored.

A second example relates to the detection of anomalies in the machines. For this purpose, the adapted sensor could be an accelerometer or an acoustic sensor, both configured to create the current signal by detecting the vibrations emitted by the machine to be monitored.

A third example is non-destructive testing of metal pipelines. In this scenario, a suitable sensor is an eddy current probe, which is configured to generate the current signal by measuring the thickness of a pipeline under monitoring.

1. A method for detecting anomalies within an environment or system, comprising the following steps:
acquiring a normal signal reflecting the normal state of the environment or system,
determining on the basis of the normal signal a probability density ƒ which models a normal behavioral state of the environment or system,
setting an information filter based on said probability density ƒ, said information filter being configured to converge toward a limit value L when it is applied to samples of a normal signal, while increasing its value in response to the detection of an anomaly,
setting a threshold value S based on said convergence limit value,
acquiring a current signal reflecting the current behavioral state of the environment or system,
sampling said current signal in a current series of N samples,
computing a result of applying the information filter to said current series of N samples,
comparing (E8) said result with said threshold value S, an anomaly being detected if said result exceeds said threshold value.

2. The method according to claim 1, wherein said threshold value S is equal to said limit value L, plus an additional values chosen according to a compromise sought between reliable detection and minimizing the number of false alarms.

3. The method according to claim 1, wherein the information filter corresponds to a first filter designed such that, when it is applied to samples of a normal signal, it converges toward a limit value which corresponds to the entropy of the probability density associated with this normal signal.

4. The method according to claim 3, wherein applying said first filter to said current series of a determined number of N samples consists in computing the natural logarithm of the value of the probability density ƒ for each of the samples xₖ, then summing these logarithms, and multiplying the result of this sum by the negative factor corresponding to the inverse of said determined number N of samples, according to the following formula:
$${I}_{i} = - \frac{1}{N} {\sum }_{{x}_{k} ∈ {W}_{i}} log f ( {x}_{k} ) \qquad [ Math . 6 ]$$

5. The method according to claim 3, wherein said threshold value S is equal to the value of the entropy H(ƒ) of the probability density ƒ, plus a value ε within an interval ranging from 1% to 20% of the absolute value of said entropy, according to the following formula:
$$S = H ( f ) + ε \qquad [ Math . 7 ]$$

6. The method according to claim 5, wherein said additional value is defined in a range between 10% and 20% of the absolute value of the entropy, in order to achieve a very low probability of false alarms, between 10⁻⁴ and 10⁻³.

7. The method according to claim 5, wherein said additional value is defined in a range between 1% and 10% of the absolute value of the entropy, to promote achieving maximum reliability in anomaly detection.

8. The method according to claim 1, wherein the information filter corresponds to a second filter which is based on said first filter, and uses a continuous function which represents an approximation of the data probability density of the current signal over a predetermined sliding window Wᵢ.

9. The method according to claim 8, wherein applying said second filter to said current series of a determined number N of samples consists in computing the natural logarithm of the value of the continuous function for each of the samples, computing the average of the results obtained for these natural logarithms, and adding the result of said average to the result of the application of the first filter to the same current series of samples, according to the following formula:
$${K}_{i} = \frac{1}{N} {\sum }_{{x}_{k} ∈ {W}_{i}} log g ( {x}_{k} ) + {I}_{i} \qquad [ Math . 8 ]$$

10. A device for detecting anomalies within an environment or system, comprising:
an acquisition module configured to acquire a current signal reflecting the current behavioral state of the environment or system,
a processor configured for:
sampling said current signal in a current series of N samples,
computing a result of applying an information filter to said current series of N samples, said information filter being based on a probability density modeling a normal behavioral state of the environment or system, said information filter being configured to converge toward a limit value when it is applied to samples of a normal signal, while increasing its value in response to the detection of an anomaly,
comparing said result with a threshold value based on said convergence limit value, an anomaly being detected if said result exceeds said threshold value, and
an output interface configured to indicate the detection of an anomaly.

11. A detection device according to claim 10, wherein the detection device comprises a magnetometer configured to generate said current signal by picking up an ambient magnetic field, comprising the Earth's field and various magnetic disturbances.

12. The detection device according to claim 10, wherein the detection device comprises an accelerometer configured to generate the current signal by picking up the vibrations originating from a machine to be monitored.

13. The detection device according to claim 10, wherein the detection device comprises a counter configured to generate the current signal by measuring the volume of data exchanged at a specific node of a computer network to be monitored.

14. The detection device according to claim 10, wherein the detection device comprises an eddy current probe configured to produce the current signal by measuring the thickness of a pipeline under monitoring.
